(19) United States
(12) Patent Application Publication
(10) Pub. No.: US 2007/0208524 A1
(43) Pub. Date: Sep. 6, 2007

(54) Long-Duration Offset Compensation of a Sensor

(75) Inventors: Mathias Niepelt, Friedberg (DE); Ralf Herbst, Nastatten (DE); Rene Zieschang, Offenbach am Main (DE)

Correspondence Address: CONTINENTAL TEVES, INC., ONE CONTINENTAL DRIVE, AUBURN HILLLS, MI, 48326-1581, US

(73) Assignee: Continental Teves AG & Co. oHG

(21) Appl. No.: 11/578,563

(22) PCT Filed: Feb. 17, 2005
(86) PCT No.: PCT/EP05/50706

§ 371 Date: Oct. 16, 2006

(30) Foreign Application Priority Data
Apr. 15, 2004 (DE) 10 2004 018802.5
Jan. 24, 2005 (DE) 10 2005 003292.5

(51) Int. Cl. G01R 35/00

(52) U.S. Cl. 702/85

(57) ABSTRACT

A method serves to compensate the offset of a sensor signal, in particular of an acceleration sensor detecting movements in the driving direction of a vehicle (longitudinal acceleration sensor). The offset of the signal during the lifetime of the vehicle adapted by means of a long-duration offset filter (LZOF). More particularly, the measuring signal for determining the offset, preferably, is not filtered in response to time but in response to travel.

### BACKGROUND OF THE INVENTION

High-class motor vehicles with electronic brake systems typically utilize a large number of sensors to detect the current driving state, such as among others yaw rate sensors, lateral acceleration sensors, longitudinal acceleration sensors, and wheel speed sensors. Especially in all-wheel vehicles, a high-precision acceleration sensor is extraordinarily important to determine the wheel slip. Lateral acceleration sensors are predominantly used in vehicles, which are equipped with an electronic stability program (ESP).

A measuring signal of a sensor generally has an offset, which must be removed for using the actual sensor signal. The offset S_{off} is subtracted from the raw signal S_{Raw} having the offset in order to calculate the useful signal Sᵤₛₑ:
Sᵤₛₑ=S_{raw}−S_{Off}

One possibility of compensating the offset of a sensor involves directing the signal of the sensor through a low-pass filter and subtracting the value of the filter from the current sensor value. However, a number of shortcomings result therefrom in the operation of a motor vehicle.

S_{Off} shall be defined as the value, which S_{Raw} adopts at the time when the physical input variable related to the reference system has the value zero. In the case of an acceleration sensor (e.g. longitudinal acceleration sensor), S_{Off} consequently is the value which the sensor furnishes as S_{Raw} when the vehicle is at standstill in the plane (when the signal of the acceleration sensor no longer shows an oscillation).

The offset S_{Off} can change in the course of the lifetime of the sensor, e.g. due to
aging (of the sensor or the components involved in signal processing),
wear,
lasting influences or temporary influences acting from the outside (e.g. deformation of the mounting device, setting properties of the chassis),
temperature effects,
other lasting changes,
   and is, hence, subjected to a long-time drift. As Sᵤₛₑ will change along with the change of S_{Off} (with S_{Raw} staying the same), the signal quality as well as the accuracy of the sensor will be reduced.

The invention describes a method for offset compensation of a sensor signal, in particular an acceleration sensor. Preferably, an acceleration sensor is concerned, which detects movements in the driving direction of a vehicle (longitudinal acceleration sensor). The objective of the invention is to adapt the offset of the signal during the lifetime of the vehicle by means of a long-duration offset filter (LZOF).

Known LZOF filters are time-responsive filters. It may occur in the application of these filters that disturbance variables or defined situations will have a negative effect on the adaptation of the signal.

The following problems may be encountered in the offset compensation of a sensor:
a) The problem ‘different speeds’: if the vehicle e.g. ascends at a slower rate than it is descending (height at the end of the travel is equal to the height at the start of the travel, speed is constant), uphill driving will have stronger effects as regards a time-responsive filter because it lasts longer. The offset calculated by the time-responsive filter is calculated at least inaccurately.
b) The problem ‘longer immobilization times on hillsides’: time-responsive filters require an additional criterion, which ‘balances’ standstill or slow driving when ascending slopes.
c) The problem ‘different rates of accelerations’: the same applies to the acceleration and deceleration with different amounts of acceleration (from 0 km/h to 100 km/h in thirty seconds and in 20 seconds back to 0 km/h again).
d) The problem ‘influence of the time of an event’: Further, influences that occur shortly before the end of the travel have a stronger effect than influences occurring at the beginning of the travel. If the vehicle (assuming constant speed) e.g. on a route of 100 km is riding the first 10 km uphill (upgrade 1=constant) and the last 10 km downhill (upgrade 1=upgrade 2=constant), downhill driving has always stronger effects than uphill driving as regards prior art low-pass filters.
e) The problem ‘different marginal conditions in the beginning and at the end of the adaptation’: different heights at travel start and travel end can cause errors in the offset. When driving uphill, for example, for several kilometers, one will learn a wrong offset due to the downgrade force that occurs when driving uphill.

### SUMMARY OF THE INVENTION

According to the method of the invention, the problems a) to e) as described above are solved by the favorable features A) to E), which will be described in the following and, either individually or in any combination desired, are advantageous embodiments of the invention:

A) The measuring signal for determining the offset is preferably not filtered in response to time but in response to travel.

To set path intervals, preferably moments are initially found out at which single intermediate calculation steps for the offset calculation are performed because this calculation is not necessarily performed in each moment of the program run of the control program (controller loop) configured as a control loop. For this purpose, an instantaneously covered partial distance e.g. from a path increment per controller loop is preferably determined from a reference value (e.g. vehicle speed on the basis of the wheel speed sensors). This can be done in a favorable manner in that, in each controller loop, the vehicle reference speed v_{ref} is added to the constant duration t_{const}. This sum is calculated again in each intermediate calculation step. An intermediate calculation step can commence at the time of the new ignition start, for example. The calculated partial travel=0 at the commencement of the travel. The partial distance increases in each controller loop when the vehicle is riding. If the instantaneous partial distance reaches or exceeds a limit value (Dₗᵢₘᵢₜ) that is fixed as a constant, a single intermediate calculation step is performed for the later calculation of a compensation value.

Several intermediate calculation steps are normally necessary for each determination of the compensation value. The determination of the calculation steps in dependence on the path covered can also be interpreted as triggering of the intermediate calculation.

After the calculation, the new value ‘partial distance (new)’ is either reset to zero or determined by the formula
Partial distance(new)=partial distance(current)−Dₗᵢₘᵢₜ.

Problem a) and automatically also problem b) are solved with this method.

The constant Dₗᵢₘᵢₜ can range between a few centimeters up to some meters depending on the requirements. A bottom limit value for determining this constant results from the distance, which the vehicle can cover at a maximally attainable speed per cycle time of the calculation system (loop). A top limit results from the necessary accuracy of the filtering operation. Values below roughly 10 meters and above roughly 50 cm are preferred, because these values still offer a good rate of accuracy.

B) Not only the raw signal S_{Raw} or the useful signal Sᵤₛₑ are used to determine the offset, but a differential signal S_{Dif} is produced from the useful signal and a reference signal (in particular the vehicle reference acceleration ∂v_{ref}/∂t calculated from the wheel signals or a signal derived from this quantity) for example according to the formula
S_{Dif}=Sᵤₛₑ−S_{Ref}.

Thus, the signal used for filtering can be rid of influences caused by vehicle accelerations to a great extent. This element of solution permits overcoming the problem dealt with in item c).

C) The actual calculation of the offset or the execution of the offset compensation in the process measure C) is performed irrespective of the steps in B), for example, when a sufficient number of values have been determined with respect to the calculation times in B). In this regard, initially an integral (Sum=S_{Sum}) with respect to S_{Dif} is produced in a determined range of time or especially distance range (for example between the beginning and the end of an ignition cycle).

The sum or the integral is calculated or produced from the time of start (T_{Start}) until the time of end (T_{End}). The duration can correspond to several ignition cycles, a minimum total distance since the last time of end T_{End}, the total ignition cycle (time during which the motor vehicle is caused by the driver to be in operation until the engine is switched off) or only to part thereof. During this time, a counter Z_{Sum} is incremented per calculation period (see item B)) or per integration step, and the number of the integration steps is thus counted. The calculation occurs at the latest at time T_{End} according to the formula:
S_{Delta}=S_{Sum}/Z_{Sum}
with S_{Delta} indicating the rate of the deviation calculated by the current filtering operation compared to the formerly memorized offset S_{Off} (this former offset is available and e.g. stored in an EEPROM since the last ignition cycle). When the former offset corresponds exactly to the currently calculated offset, S_{Delta} is equal to zero. In this case, the current value of S_{Off} corresponds to the stored value of S_{Off}, and there is no deviation.

According to another embodiment, the method can be supplemented by a limitation of the range of values. When the offset compensation covers several ignition cycles, especially the parameters S_{Sum} and Z_{Sum} are stored in a non-volatile memory in the condition ‘ignition off’ and read out again from the non-volatile memory during the next vehicle start. As this occurs, the parameters can be stored in a scaled or non-scaled fashion. This element will overcome mainly those problems related to item d) and also items a) and c).

D) Advantageously, the method of the invention can be supplemented in that top and bottom limit values are fixed for the absolute offset value S_{Off} in order to rule out that the method corrects the offset value to an extent, which exceeds the physically possible limits of an offset deviation.

According to another preferred step of the method, a limit value can be fixed in addition, beyond which a correction of the offset in terms of the absolute value irrespective of the sign is not allowed. This prevents a correction S_{Off} in the current compensation process from being excessive. The limit value used for this purpose can be calculated especially based on the covered route for this compensation process. For example, the limit value results from Z_{Sum} or any other desired route information. The longer the path covered in the current filtering operation, the less risk there is that the LZOF filter indicates a wrong value due to different start and end heights. The correlation between the distance covered and the limit value determined herein can be linear or non-linear. The maximum allowable value can also be determined in a simple manner from a constant parameter.

Thus, the problem referred to in item e) is overcome.

E) To prevent that the learning process is influenced negatively by erroneous input signals or implausible driving situations, it is possible to use an error counter, which is incremented in particular in one or in a combination of the following situations.

The error counter is preferably incremented when erroneous input signals prevail, for example, depending on the calculation of the reference speed, either when at least one wheel sensor signal is disturbed (or its signal processing chain), or when at least two wheel sensor signals are disturbed (or their signal processing chain), or when the acceleration sensor or its signal processing chain is disturbed.

The error counter is preferably incremented when implausible or unusual driving situations prevail, where the learning algorithm could be influenced negatively due to an erroneously calculated reference speed, in particular when one of the control functions, i.e. anti-lock system, traction control system, electronic stability program, electronic brake assist system, hydraulic brake assist system, is active. A combination or selection of these control functions or other control functions is possible, it being preferably arranged in this case according to the control functions available in the vehicle and their vehicle-related influences on the learning algorithm.

In the presence of erroneous input signals or implausible driving situations, it is preferred to interrupt the calculation of S_{Sum} and/or Z_{Sum}. Furthermore, it is favorably checked at time T_{End} and when storing S_{Sum} and Z_{Sum} in the non-volatile memory, whether the error counter has exceeded a limit value, which can comprise a constant threshold and a travel-responsive component. Once this threshold is exceeded, the learning algorithm is newly initialized by resetting the parameters S_{Sum} and Z_{Sum} in the non-volatile memory and prohibiting a correction of the offset.

The method of the invention has the following advantages in addition to the solution of the above problems:

1. The learnt offset is not influenced when a motor vehicle is standing on a slope, because no distance is covered then.

2. When a vehicle is slowly riding, e.g. off-road uphill or when ascending during stop-and-go, the method brings about an automatic weighting so that undesirable influencing of the offset found is diminished.

3. At high speeds of the motor vehicle, the roadway is mostly much more plane (e.g. on a motor highway) than in slow travel (e.g. in a parking garage). The method of the invention takes this fact automatically into consideration.

4. It is advantageous for the implementation on a microcomputer that the method is only based on simple calculation steps. (Addition, subtraction and comparisons are needed almost exclusively).

It is likewise possible to calculate per controller loop a sum or an integral, e.g. according to the formula:
Vehicle reference speed*constant*measuring signal.

This allows achieving a compensation of similar precision or even a more precise compensation. However, this alternative method requires more calculation time.

Compensation with a rate of accuracy that is further improved can be achieved when the limit value Dₗᵢₘᵢₜ is maintained relatively low and the integral is produced at higher speeds in such a fashion that integration occurs several times per calculation step. S_{Dif} is then stored e.g. two times (or three times depending on speed).

During compensation, it is also possible to include acceleration and deceleration phases in the calculation by way of an inquiry. In this case, it may even be omitted to produce the value S_{Ref}.

Advantageously, the method of the invention can additionally be used to calculate a height profile of the travel. The value calculated from S_{Sum} is used for this purpose. The precondition is that the sensor has already been adapted properly, that means, S_{Delta} has already low values. This height profile can also be employed as a supporting signal for navigation systems in another preferred application.

Besides, the method can be used to indicate the distance covered. This information could e.g. be of interest when determining the tachometer reading.

The problem may be encountered in the solution described that offset compensation is not possible in a vehicle being moved only over short distances. To solve this problem, the method of the invention is preferably supplemented by a process step, in which a certain value is defined, allowing the offset to be corrected irrespective of the distance covered in each ignition cycle, no matter how short the latter is.

In the following, the invention will be explained in detail by way of an example.

### BRIEF DESCRIPTION OF THE DRAWING

In the drawing,

FIG. 1 shows a survey of a course of procedure according to the invention.

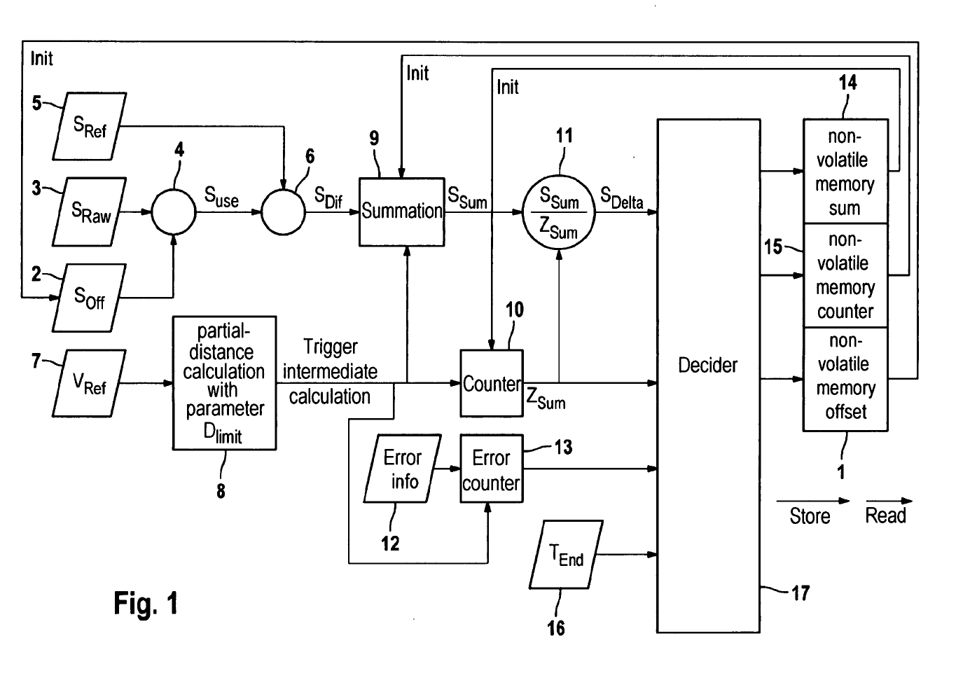

### DETAILED DESCRIPTION OF THE DRAWING

During start of the vehicle, the offset S_{Off} determined the last is read out of the non-volatile memory (1) and made available for further processing (process step 2). Further, the sensor, e.g. an acceleration sensor, determines the raw signal S_{raw} having an offset (process step 3). The offset S_{Off} is subtracted from the raw signal S_{raw} having an offset in order to calculate the useful signal Sᵤₛₑ (process step 4):
Sᵤₛₑ=S_{raw}−S_{Off}

This useful signal Sᵤₛₑ can now be employed by the vehicle components (for example ESP) provided therefor.

Further, not only the raw signal S_{raw} or the useful signal Sᵤₛₑ is determined, but a differential signal S_{Dif} is produced from the useful signal and a reference signal S_{Ref} (in particular the vehicle reference acceleration ∂v_{ref}/∂t calculated from the wheel signals or a signal derived from this quantity) according to the formula
S_{Dif}=Sᵤₛₑ−S_{Ref}
(process steps 5 and 6). Thus, the signal used for filtering can be rid of influences caused by vehicle accelerations to a very great extent.

As the quality of the offset S_{Off} becomes worse with time, a new determination of the offset S_{Off} is performed travel-responsively. Preferably, moments are initially determined for setting travel intervals, at which individual intermediate calculation steps for the offset calculation are performed, because this calculation is not imperatively performed at each moment of the program run of the control program configured as a control loop (controller loop).

To this end, an instantaneously covered partial distance from a distance increment per controller loop is determined from the reference value V_{Ref} (process step 7, e.g. vehicle speed based on the wheel speed sensors). This can preferably be done in that in each controller loop, the vehicle reference speed V_{Ref} is added to the constant period t_{Const}. This sum is calculated anew with each intermediate calculation step. An intermediate calculation step can start at the moment of the new ignition cycle, for example. The calculated partial distance=0 at the commencement of travel. The partial distance increases in each controller loop when the vehicle is riding. When the partial distance reaches or exceeds a limit value Dₗᵢₘᵢₜ (process step 8) being set as a constant, a single intermediate calculation step is performed for the later calculation of the compensation value.

Several intermediate calculation steps are normally necessary for each determination of the compensation value. The determination of the calculation steps in dependence on the path covered can also be interpreted as triggering of the intermediate calculation.

After the calculation, the new value ‘partial distance (new)’ is either reset to zero or determined by the formula
partial distance(new)=partial distance(current)−Dₗᵢₘᵢₜ.

The actual calculation of the offset or the execution of the offset compensation is performed when a sufficient number of values have been determined with respect to the calculation times. In this regard, initially an integral (Sum=S_{Sum}) with respect to S_{Dif} is favorably produced in a determined range of distance (process step 9).

Further, a counter Z_{Sum} is incremented per calculation time or per integration step, and the number of the integration steps is thus counted (process step 10). In this respect, part of the summands or the counters can be read out from the non-volatile memories (14, 15), especially during short travels. Subsequently, the calculation occurs according to the formula (process step 11):
S_{Delta}=S_{Sum}/Z_{Sum}
with S_{Delta} indicating the rate of the deviation calculated by the current filtering operation compared to the formerly memorized offset S_{Off}. This former offset is still stored in the non-volatile memory (1, e.g. EEPROM). When the former offset corresponds exactly to the currently calculated offset, S_{Delta} is equal to zero. In this case, the current value of S_{Off} corresponds to the stored value of S_{Off}, and there is no deviation. If S_{Delta} is unequal zero, a new offset S_{Off} is produced according to the allocation:
S_{Off}=S_{Off}+S_{Delta}.

To prevent that the learning process is influenced negatively by erroneous input signals or implausible driving situations (process step 12), an error counter is used, which is incremented in particular in one or in a combination of the following situations.

The error counter is preferably incremented (process step 13) when erroneous input signals prevail, for example, depending on the calculation of the reference speed, either when at least one wheel sensor signal is disturbed (or its signal processing chain), or when at least two wheel sensor signals are disturbed (or their signal processing chain), or when the acceleration sensor or its signal processing chain is disturbed.

The error counter is preferably incremented (process step 13) when implausible or unusual driving situations prevail, where the learning algorithm could be influenced negatively due to an erroneously calculated reference speed, in particular when one of the control functions, i.e. anti-lock system, traction control system, electronic stability program, electronic brake assist system, hydraulic brake assist system, is active. A combination or selection of these control functions or other control functions is possible, it being preferably arranged in this case according to the control functions available in the vehicle and their vehicle-related influences on the learning algorithm.

In the presence of erroneous input signals or implausible driving situations, it is preferred to check at time T_{End} (process step 16) and when storing S_{Sum} and Z_{Sum} in the non-volatile memory (process step 17), whether the error counter has exceeded a limit value, which can comprise a constant threshold and a travel-responsive component. Once this threshold is exceeded, the learning algorithm is newly initialized by resetting the parameters S_{Sum} and Z_{Sum} in the non-volatile memory and prohibiting a correction of the offset. If this threshold is not exceeded, the instantaneously valid values for S_{Off}, S_{Sum} and Z_{Sum} are stored in the non-volatile memories (1, 14, 15).

When the offset compensation covers several ignition cycles, especially the parameters S_{Sum} and Z_{Sum} are stored in a non-volatile memory in the condition ‘ignition off’ and read out again from the non-volatile memory during the next vehicle start. As this occurs, the parameters can be stored in a scaled or non-scaled fashion.

1-24. (canceled)

25. A method for the offset compensation of an electric signal of a sensor by determining a compensation value S_{Off}, comprising the step of adjusting the compensation value S_{Off} on a long-term basis over the course of the lifetime of the sensor.

26. The method as claimed in claim 25,
wherein the compensation value S_{Off} is adjusted depending on a distance covered by the vehicle.

27. The method as claimed in claim 26,
comprising the steps of
taking into account distance intervals for fixing intermediate calculation moments, and
triggering a current intermediate calculation for the calculation of the compensation value at the intermediate calculation moments.

28. The method as claimed in claim 25,
comprising the step of determining a sequence of compensation correction values, wherein the compensation value S_{Off} is only determined when a sufficient number of compensation correction values have been determined.

29. The method as claimed in claim 28,
comprising the step of weighting at least the compensation values S_{Off} or the compensation correction values corresponding to the distances covered, at which the respective values prevailed.

30. The method as claimed in claim 25,
comprising the step of compensating the offset, wherein the offset compensation is only performed when a sufficient number of compensation values S_{Off} have been determined.

31. The method as claimed in claim 25,
wherein top and bottom limit values are fixed for the compensation value S_{Off}, which the compensation value S_{Off} is not allowed to exceed.

32. The method as claimed in claim 31,
wherein the top and bottom limit values have the same absolute value but opposite signs.

33. The method as claimed in claim 25,
wherein for the offset compensation, apart from the raw signal of the sensor, also a reference signal S_{Ref} of another sensor is used, which represents a measured variable of the sensor or a quantity from which the measured variable can be derived, the method comprising the step of producing a difference S_{Dif} of an offset-compensated useful signal Sᵤₛₑ and the reference signal S_{Ref} is produced.

34. The method as claimed in claim 33,
comprising the step of producing an integral or a sum S_{Sum} with respect to the difference S_{Dif} within the limits of a determined time or distance range, based on which the correction of the sensor offset is determined.

35. The method as claimed in claim 34,
wherein a counter Z_{Sum} is incremented per integration step or per summation step, and the number of steps is thus counted.

36. The method as claimed in claim 35,
wherein the compensation correction value is determined according to the formula S_{Delta}=S_{Sum}/Z_{Sum}.

37. The method as claimed in claim 36,
wherein a distance covered is determined from the counter Z_{Sum}.

38. The method as claimed in at least one of claim 34,
wherein a height profile of the travel is determined from the value S_{Sum}.

39. The method as claimed in 34,
wherein a predetermined value for the distance range is defined, and in the case that a covered distance is smaller than the predetermined value, correction of the compensation value S_{Off} is allowed irrespective of the distance covered.

40. The method as claimed in claim 34,
wherein a predetermined value for the distance range is defined, and in the case that a covered distance is smaller than the predetermined value, already determined intermediate values are stored in a non-volatile memory.

41. The method as claimed in claim 25,
comprising the step of determining acceleration and deceleration phases by way of an inquiry during the compensation, and omitting the compensation during such a phase.

42. The method as claimed in claim 25,
comprising the step of checking for an erroneous input signal.

43. The method as claimed in claim 25,
comprising the step of checking for an unusual driving situation.

44. The method as claimed in claim 43,
wherein it is checked, whether at least one of the control functions is active. which are members of the group consisting of anti-lock system, traction control system, electronic stability program, electronic brake assist system, and hydraulic brake assist system.

45. The method as claimed claim 25,
wherein an error counter is used.

46. The method as claimed in claim 45,
comprising the step of increasing the error counter in the event of an erroneous input signal and in the event of an unusual driving situation.
